(19) United States
(12) Patent Application Publication
(10) Pub. No.: US 2024/0162014 A1
(43) Pub. Date: May 16, 2024

(54) PROCESS CHAMBER, SUBSTRATE TREATING APPARATUS INCLUDING THE SAME, AND OPERATING METHOD OF THE SUBSTRATE TREATING APPARATUS

(71) Applicant: Samsung Electronics Co., Ltd., Suwon-si (KR)

(72) Inventors: Heewon Min, Suwon-si (KR); Dongyun Yeo, Suwon-si (KR); Songyun Kang, Suwon-si (KR); Juho Kim, Suwon-si (KR); Seungbin Lim, Suwon-si (KR)

(21) Appl. No.: 18/383,211

(22) Filed: Oct. 24, 2023

(30) Foreign Application Priority Data
Nov. 11, 2022 (KR) 10-2022-0150970

(51) Int. Cl. H01J 37/32

(52) U.S. Cl. CPC H01J 37/32513; H01J 2237/166; H01J 2237/24507

(57) ABSTRACT

A process chamber includes a housing providing a process space where plasma processing is performed, a first opening/closing device in a side wall of the housing, the first opening/closing device including a first frame and at least one opening/closing blade connected to the first frame, and a second opening/closing device on an outside of the side wall of the housing and on a same line as the first opening/closing device, the second opening/closing device including a second frame and an opening/closing door structure connected to the second frame, wherein the first opening/closing device and the second opening/closing device are configured to maintain a vacuum state of the process space.

### CROSS-REFERENCE TO RELATED APPLICATION

This application is based on and claims priority under 35 U.S.C. § 119 to Korean Patent Application No. 10-2022-0150970, filed on Nov. 11, 2022, in the Korean Intellectual Property Office, the disclosure of which is incorporated by reference herein in its entirety.

### BACKGROUND

Aspects of the inventive concept relate to a process chamber, a substrate treating apparatus including the same, and an operating method of the substrate treating apparatus. More particularly, aspects of the inventive concept relate to a process chamber in which plasma processing is performed, a substrate treating apparatus including the same, and an operating method of the substrate treating apparatus.

In semiconductor manufacturing processes, plasma is used in various processes such as an etching process, a vapor deposition process, and a cleaning process. To ensure the quality of semiconductor devices manufactured by these various processes, the density of plasma used in the various processes needs to be uniformly maintained. Accordingly, during the various processes, the density of plasma generated in a process chamber is measured. To measure the density of plasma, a plasma density measurement probe is introduced into the process chamber in which the plasma is generated. In the process of introducing the plasma density measurement probe into the process chamber, a vacuum state inside the process chamber may not be maintained. Therefore, approaches for maintaining the vacuum state are desired.

### SUMMARY

Aspects of the inventive concept provide a process chamber capable of maintaining a vacuum state therein even during a process of measuring the density of plasma generated therein, a substrate treating apparatus including the process chamber, and an operating method of the substrate treating apparatus.

According to an aspect of the inventive concept, there is provided a process chamber including a housing providing a process space where plasma processing is performed, a first opening/closing device in a side wall of the housing, the first opening/closing device including a first frame and at least one opening/closing blade connected to the first frame, and a second opening/closing device on an outside of the side wall of the housing and on a same line as the first opening/closing device, the second opening/closing device including a second frame and an opening/closing door structure connected to the second frame, wherein the first opening/closing device and the second opening/closing device are configured to maintain a vacuum state of the process space.

According to another aspect of the inventive concept, there is provided a substrate treating apparatus including a process chamber including a housing providing a process space where plasma processing is performed, a first opening/closing device in a side wall of the housing, the first opening/closing device including a first frame and at least one opening/closing blade connected to the first frame, wherein an inner portion of the at least one opening/closing blade forms a first opening, and a second opening/closing device on an outside of the side wall of the housing and on a same line as the first opening/closing device, the second opening/closing device including a second frame having a circular shape and an opening/closing door structure connected to the second frame, a substrate support inside the process chamber and configured to support a substrate, an upper electrode above the substrate support and spaced apart from substrate support, a power generator configured to apply, to the upper electrode, source power for generating plasma in the process space of the process chamber, and a seal structure connected to the second opening/closing device, wherein the first opening/closing device, the second opening/closing device, and the seal structure are configured to maintain a vacuum state of the process space.

According to a further aspect of the inventive concept, there is provided an operating method of a substrate treating apparatus. The operating method includes closing a first opening/closing device by blocking a first opening by moving an opening/closing blade of the first opening/closing device and closing a second opening/closing device by blocking a second opening by moving an opening/closing door structure of the second opening/closing device in a horizontal direction, connecting a seal structure to the second opening/closing device that has been closed, opening the first opening/closing device by forming the first opening by moving the opening/closing blade of the first opening/closing device and opening the second opening/closing device by opening the second opening by moving the opening/closing door structure of the second opening/closing device in the horizontal direction, and introducing a plasma density measurement probe into a process space of a process chamber through the second opening of the second opening/closing device that is open and the first opening of the first opening/closing device that is open, wherein a vacuum state of the process space is maintained by performing an opening/closing operation of the first opening/closing device, an opening/closing operation of the second opening/closing device, and stretching and compressing of the seal structure.

### BRIEF DESCRIPTION OF THE DRAWINGS

Embodiments will be more clearly understood from the following detailed description taken in conjunction with the accompanying drawings in which:

FIG. 1A is a cross-sectional view of a substrate treating apparatus according to an embodiment; FIG. 1B is an enlarged cross-sectional view of a region EX in FIG. 1A;

FIG. 2A is a cross-sectional view of a substrate treating apparatus according to an embodiment; FIG. 2B is an enlarged cross-sectional view of a region EX in FIG. 2A;

FIG. 3 is a plan view of a first opening/closing device according to an embodiment;

FIG. 4 is a plan view of a second opening/closing device according to an embodiment; and

FIGS. 5A to 5D are cross-sectional views illustrating the operation of a substrate treating apparatus, according to an embodiment.

### DETAILED DESCRIPTION OF THE EMBODIMENTS

Hereinafter, embodiments are described in detail with reference to the accompanying drawings. In the drawings, like reference characters denote like elements, and redundant descriptions thereof will be omitted.

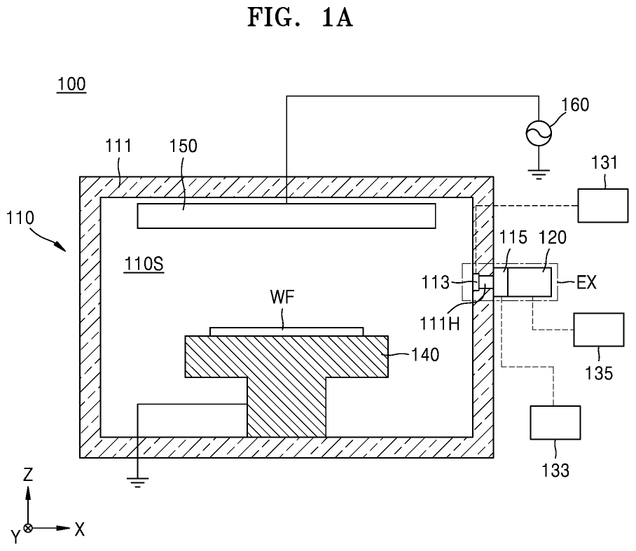

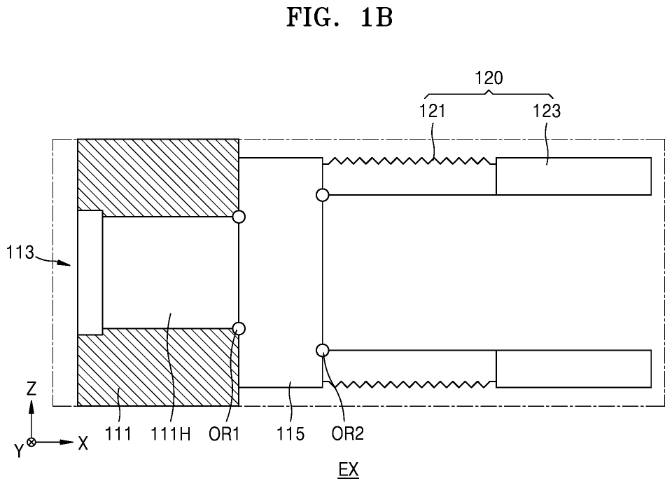

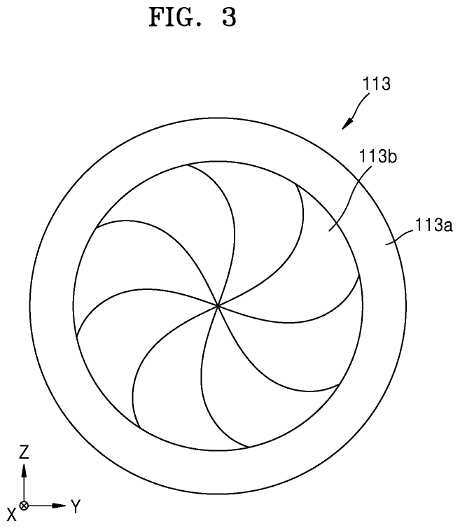

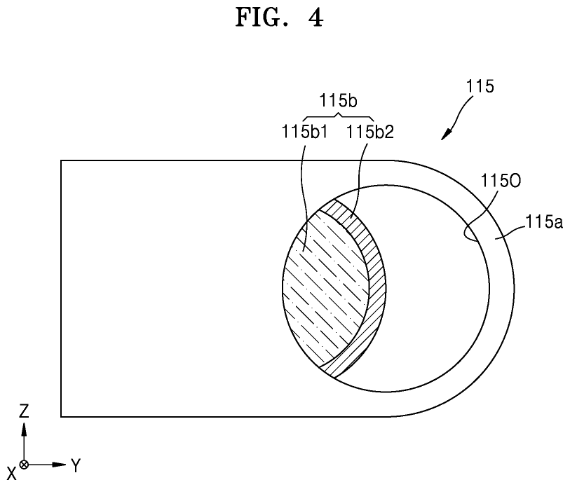

FIG. 1A is a cross-sectional view of a substrate treating apparatus 100 according to an embodiment. FIG. 1B is an enlarged cross-sectional view of a region EX in FIG. 1A. FIG. 3 is a plan view of a first opening/closing device 113 according to an embodiment. FIG. 4 is a plan view of a second opening/closing device 115 according to an embodiment.

Referring to FIGS. 1A and 1B, the substrate treating apparatus 100 may include a process chamber 110, a seal structure 120, a substrate support 140, an upper electrode 150, and a power generator 160.

The process chamber 110 may provide a process space 110S in which plasma processing is performed on a substrate WF. The substrate support 140 and the upper electrode 150 may be accommodated in the process space 110S of the process chamber 110.

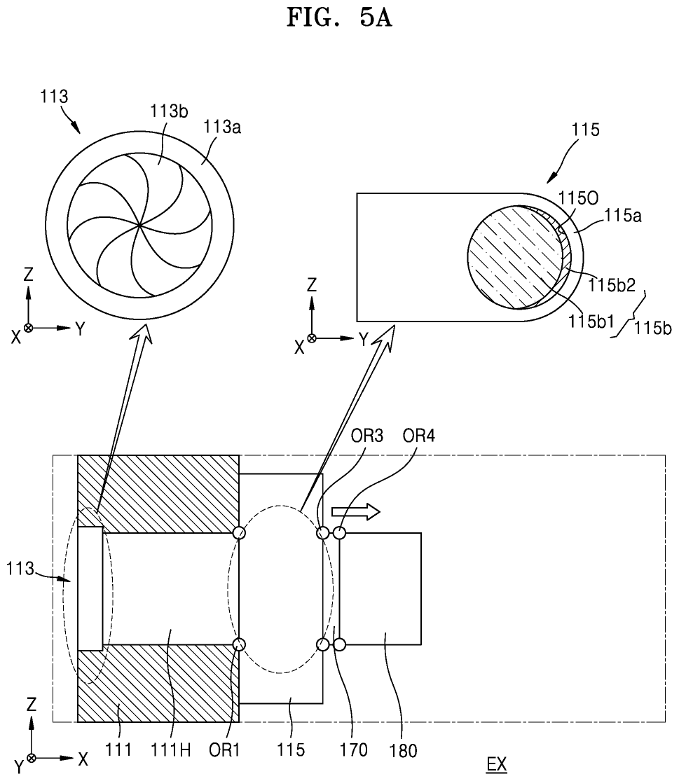

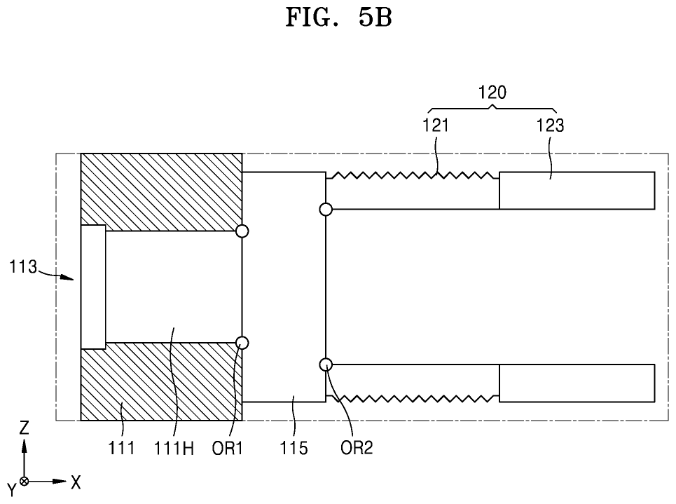

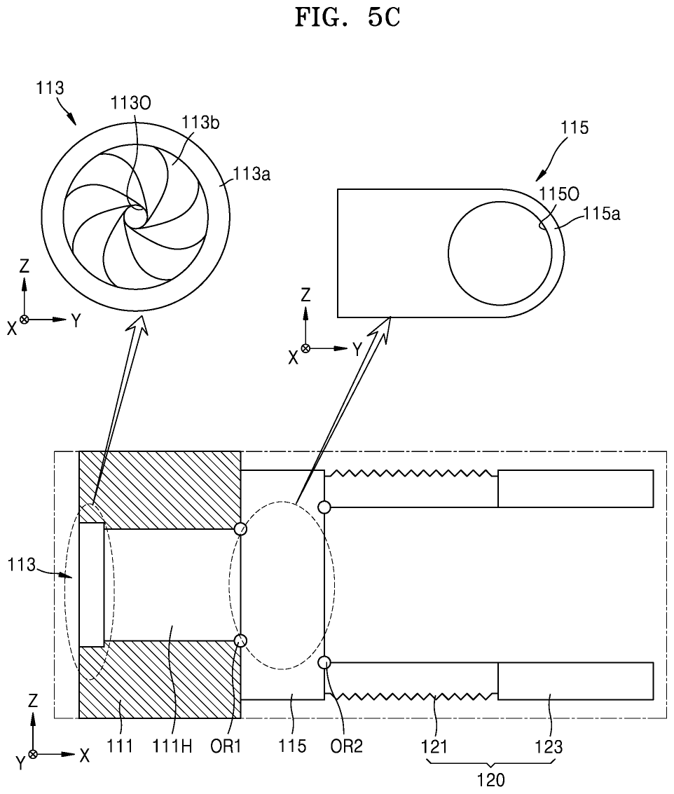

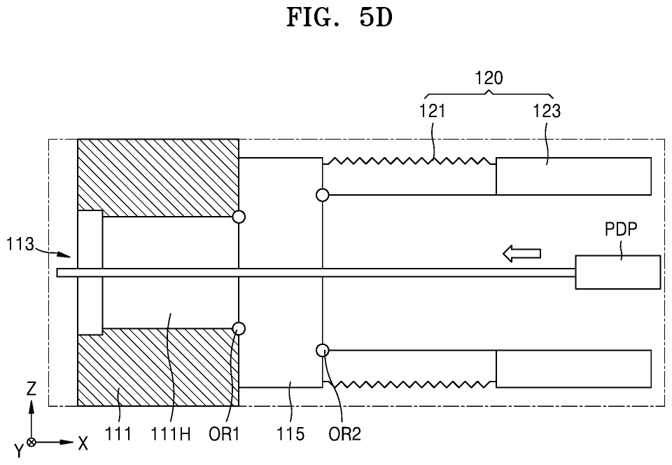

The process chamber 110 may include a housing 111, the first opening/closing device 113, and the second opening/closing device 115. The housing 111 may include within the process space 110S in which plasma processing is performed on the substrate WF. For example, the housing 111 may have a cylindrical shape. In an embodiment, the housing 111 may have a through hole 111H in a side wall thereof. The through hole 111H may extend through the side wall of the housing 111 in a first horizontal direction (e.g., the X direction). The through hole 111H may function as a passage, through which a plasma density measurement probe PDP (in FIG. 5D) for measuring the density of plasma generated in the process space 110S is introduced from the outside of the process chamber 110 into the process space 110S during plasma processing.

Referring to FIGS. 1A, 1B, and 3, the first opening/closing device 113 may be in a side wall of the housing 111. For example, the first opening/closing device 113 may be in the side wall of the housing 111 and between the through hole 111H and the process space 110S. Accordingly, when the first opening/closing device 113 is opened, the process space 110S may be in communication with the through hole 111H. When the first opening/closing device 113 is closed, the process space 110S may not be in communication with the through hole 111H.

In an embodiment, the first opening/closing device 113 may have a circular shape. In an embodiment, the diameter of the first opening/closing device 113 may be greater than or equal to the diameter of the through hole 111H.

In an embodiment, the first opening/closing device 113 may include a first frame 113a and at least one opening/closing blade 113b. The first frame 113a may have a ring shape. The first frame 113a may be coupled and fixed to the side wall of the housing 111. The first frame 113a may provide a movement path of the opening/closing blade 113b.

In an embodiment, there may be a plurality of opening/closing blades 113b. In this case, respective inner portions of the opening/closing blades 113b may together form a first opening 1130 (in FIG. 5C). In an embodiment, based on the movement of the opening/closing blades 113b, the diameter of the first opening 1130 may be adjusted. Accordingly, the plasma density measurement probe PDP (in FIG. 5D) having any one of various sizes may be introduced in to the process space 110S through the first opening 1130 of the first opening/closing device 113. Although it is illustrated in FIG. 3 that there are eight opening/closing blades 113b, the number of opening/closing blades 113b is not limited thereto.

In an embodiment, at least one opening/closing blade 113b may be configured to move clockwise or counterclockwise along a movement path provided by the first frame 113a. When the opening/closing blade 113b moves counterclockwise, the first opening/closing device 113 that has been closed may be opened to form the first opening 1130, or the diameter of the first opening 1130 may increase. Contrarily, when the opening/closing blade 113b moves clockwise, the first opening/closing device 113 may be closed such that the first opening 1130 disappears, or the diameter of the first opening 1130 may decrease.

In an embodiment, the first frame 113a and the opening/closing blade 113b may include the same material as each other. For example, the first frame 113a and the opening/closing blade 113b may include or may be formed of aluminum.

Referring to FIGS. 1A, 1B, and 4, the second opening/closing device 115 may be on an outside wall of the housing 111. At this time, the second opening/closing device 115 may overlap in the first horizontal direction (the X direction) with the through hole 111H in the side wall of the housing 111. Accordingly, when the second opening/closing device 115 is opened, the through hole 111H may be in communication with the outside of the process chamber 110. When the second opening/closing device 115 is closed, the through hole 111H may not be in communication with the outside of the process chamber 110.

In an embodiment, the second opening/closing device 115 may include a second frame 115a and an opening/closing door structure 115b. The second frame 115a may include a second opening 1150. The second opening 1150 may overlap in the first horizontal direction (the X direction) with the through hole 111H in the side wall of the housing 111. The diameter of the second opening 1150 may be greater than or equal to the diameter of the through hole 111H. The second opening 1150 may have a circular shape but is not limited thereto.

In an embodiment, the opening/closing door structure 115b may be configured to move in a second horizontal direction (e.g., the Y direction). For example, the opening/closing door structure 115b may move toward or away from the second opening 1150 in the second horizontal direction (the Y direction). When the opening/closing door structure 115b moves toward the second opening 1150 in the second horizontal direction (the Y direction), the opening/closing door structure 115b may block the second opening 1150 such that the second opening/closing device 115 that has been opened may be closed. Contrarily, when the opening/closing door structure 115b moves away from the second opening 1150 in the second horizontal direction (the Y direction), the second opening/closing device 115 that has been closed may be opened. In some embodiments, the opening/closing door structure 115b may be configured to move in a vertical direction (the Z direction). For example, the opening/closing door structure 115b may move toward or away from the second opening 1150 in the vertical direction (the Z direction). In some embodiments, the opening/closing door structure 115b may be configured to move in a diagonal direction. For example, the opening/closing door structure 115b may move toward or away from the second opening 1150 in the diagonal direction.

In an embodiment, the opening/closing door structure 115b may have a shape that is substantially the same as or similar to the shape of the second opening 1150. For example, when the second opening 1150 has a circular shape, the opening/closing door structure 115b may also have a circular shape. In this case, the size of the shape of the opening/closing door structure 115b may be greater than or equal to the size of the shape of the second opening 1150.

In an embodiment, the opening/closing door structure 115b may include an opening/closing door 115b1 and a door seal 115b2 surrounding the opening/closing door 115b1. For example, the opening/closing door 115b1 may include or may be formed of a metal material, such as aluminum. In an embodiment, the door seal 115b2 may include an O-ring seal. Accordingly, when the opening/closing door structure 115b blocks the second opening 1150, the door seal 115b2 may maintain the sealing of the through hole 111H such that the through hole 111H is not in communication with the outside of the process chamber 110.

In an embodiment, the first opening/closing device 113 and the second opening/closing device 115 may be at a higher vertical level (i.e., in the Z direction) than the substrate support 140. Accordingly, the plasma density measurement probe PDP (in FIG. 5D) may be introduced into the process chamber 110 through the second opening/closing device 115, which has been opened, the through hole 111H, and the first opening/closing device 113, which has been opened, to be located above the substrate WF supported by the substrate support 140 and measure the density of plasma formed above the substrate WF.

Referring back to FIGS. 1A and 1B, in an embodiment, the substrate treating apparatus 100 may further include a first O-ring seal OR1 between a side wall of the process chamber 110 and the second opening/closing device 115. The first O-ring seal OR1 may maintain the sealing of the through hole 111H from the outside of the process chamber 110.

The seal structure 120 may be connected to the second opening/closing device 115. In an embodiment, the seal structure 120 may be configured to be removable from the second opening/closing device 115. The seal structure 120 may maintain the vacuum state of the process space 110S during plasma processing even when the plasma density measurement probe PDP (in FIG. 5D) is moved in the process space 110S to measure the density of plasma generated in the process space 110S.

In an embodiment, the seal structure 120 may include a bellows seal 121 and a magnetic fluid seal 123. At this time, the bellows seal 121 may be connected to the second opening/closing device 115, and the magnetic fluid seal 123 may be connected to the bellows seal 121. In an embodiment, the bellows seal 121 may include an elastic, flexible tube. The flexible tube may be stretched or compressed by a third power unit 135, which is described below. In an embodiment, the magnetic fluid seal 123 may include a magnet and a magnetic fluid. In an embodiment, the bellows seal 121 may be configured to be removable from the second opening/closing device 115, and the magnetic fluid seal 123 may be configured to be removable from the bellows seal 121. Because the seal structure 120 includes the bellows seal 121, the vacuum state of the process space 110S may be maintained even when the plasma density measurement probe PDP (in FIG. 5D) is moved in the process space 110S in the first horizontal direction (the X direction). Because the seal structure 120 includes the magnetic fluid seal 123, the vacuum state of the process space 110S may be maintained even when the plasma density measurement probe PDP (in FIG. 5D) is rotated and moved in the process space 110S.

In an embodiment, the substrate treating apparatus 100 may further include a second O-ring seal OR2 between the second opening/closing device 115 and the seal structure 120. The second O-ring seal OR2 may maintain the sealing of the through hole 111H from the outside of the process chamber 110.

In an embodiment, the substrate treating apparatus 100 may further include a first power unit 131. The first power unit 131 may drive the opening/closing blade 113b of the first opening/closing device 113 to open or close the first opening/closing device 113. For example, the first power unit 131 may open or close the first opening/closing device 113 by providing power to allow the opening/closing blade 113b to move clockwise or counterclockwise. For example, the first power unit 131 may include a motor but is not limited thereto.

In an embodiment, the substrate treating apparatus 100 may further include a second power unit 133. The second power unit 133 may open or close the second opening/closing device 115 by driving the opening/closing door structure 115b of the second opening/closing device 115. For example, the second power unit 133 may open or close the second opening/closing device 115 by providing power to the opening/closing door structure 115b such that the opening/closing door structure 115b moves toward or away from the second opening 1150. For example, the second power unit 133 may include a motor but is not limited thereto.

In an embodiment, the substrate treating apparatus 100 may further include the third power unit 135. The third power unit 135 may stretch or compress the bellows seal 121, thereby maintaining the sealing of the through hole 111H from the outside of the process chamber 110. For example, the third power unit 135 may include an actuator but is not limited thereto.

The substrate support 140 may be provided in the process space 110S of the process chamber 110. The substrate support 140 may be configured to support the substrate WF in the process space 110S. For example, the substrate support 140 may include an electrostatic chuck configured to support the substrate WF by using an electrostatic force, but is not limited thereto. In an embodiment, the substrate support 140 may function as a lower electrode for generating plasma in the process space 110S. In an embodiment, a ground electrode may be connected to the substrate support 140.

The upper electrode 150 may be provided in the process space 110S of the process chamber 110 and may be arranged above the substrate support 140 to face the substrate support 140. The upper electrode 150 may function to generate plasma in the process space 110S. For example, the upper electrode 150 may include a shower head configured to supply a plasma process gas into the process space 110S, but is not limited thereto.

The power generator 160 may be configured to apply source power for generating plasma to the upper electrode 150. For example, the power generator 160 may apply radio frequency (RF) power to the upper electrode 150.

In the case of a process chamber according to the related art and a substrate treating apparatus including the same, an opening/closing device for maintaining the vacuum state of the process chamber is not separately included in the process chamber. Accordingly, in the process of introducing a plasma density measurement probe into the process chamber and measuring the density of plasma generated in the process chamber using the plasma density measurement probe, a process space of the process chamber is in communication with the outside of the process chamber, and therefore, the vacuum state of the process chamber is not maintained. In this case, after the density of plasma is measured, a separate process of changing the process space of the process chamber into the vacuum state needs to be performed, and therefore, the productivity of semiconductor manufacturing processes performed using the process chamber and the substrate treating apparatus including the same decreases. Contrarily, according to aspects of the present inventive concept, the substrate treating apparatus 100 includes the process chamber 110 including the first opening/closing device 113 and the second opening/closing device 115 and the seal structure 120 connected to the second opening/closing device 115, and accordingly, the process space 110S of the process chamber 110 may be maintained in a vacuum state even during a process of introducing the plasma density measurement probe PDP into the process chamber 110 and measuring the density of plasma generated in the process chamber 110 by using the plasma density measurement probe PDP. As a result, after the density of plasma is measured, a separate process of changing the process space 110S of the process chamber 110 into the vacuum state is not performed, and therefore, the productivity of semiconductor manufacturing processes may increase.

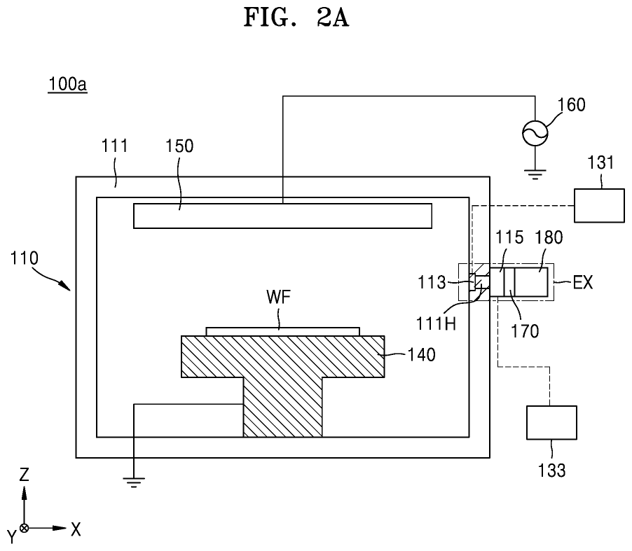

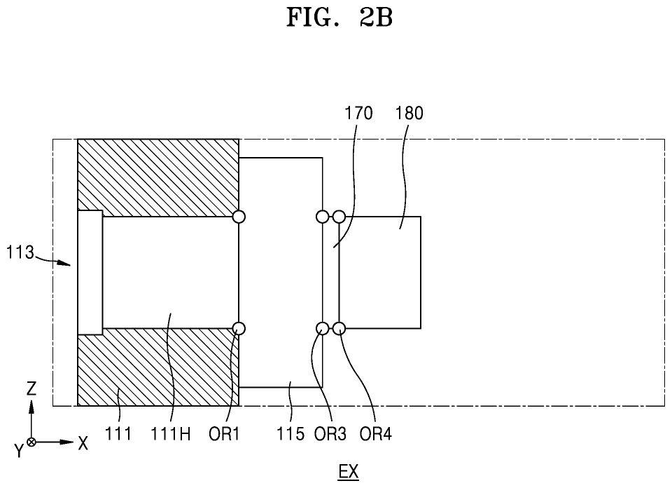

FIG. 2A is a cross-sectional view of a substrate treating apparatus 100a according to an embodiment. FIG. 2B is an enlarged cross-sectional view of a region EX in FIG. 2A. The elements of the substrate treating apparatus 100a illustrated in FIGS. 2A and 2B are similar to those of the substrate treating apparatus 100 described with reference to FIGS. 1A and 1B, and thus, differences therebetween are mainly described.

Referring to FIGS. 2A and 2B, the substrate treating apparatus 100a may include the process chamber 110, the substrate support 140, the upper electrode 150, the power generator 160, a viewport 170, and an optical emission spectroscopy (OES) device 180. The substrate treating apparatus 100a may be obtained by detaching the seal structure 120 from the second opening/closing device 115 of the substrate treating apparatus 100 of FIGS. 1A and 1B and sequentially attaching the viewport 170 and the OES device 180 to the second opening/closing device 115. At this time, plasma processing may be being performed on the substrate WF in the process chamber 110 of the substrate treating apparatus 100a.

The process chamber 110 may include the housing 111, the first opening/closing device 113, and the second opening/closing device 115. When plasma processing is performed in the housing 111, the first opening/closing device 113 may be closed, and the second opening/closing device 115 may be opened. Accordingly, plasma light generated in the process space 110S may be provided to the OES device 180 after passing through the second opening/closing device 115 that has been opened.

The substrate support 140 may support the substrate WF while plasma processing is being performed in the process space 110S. The upper electrode 150 and the power generator 160 may generate plasma, which is used in the plasma processing, in the process space 110S.

The viewport 170 may be connected to the second opening/closing device 115. In an embodiment, the viewport 170 may be configured to be removable from the second opening/closing device 115. In an embodiment, the viewport 170 may be configured to monitor the process space 110S of the process chamber 110. In an embodiment, the viewport 170 may function as a passage, through which plasma light generated in the process space 110S is transmitted and provided to the OES device 180. For example, the viewport 170 may include or may be formed of quartz but is not limited thereto.

In an embodiment, the substrate treating apparatus 100a may further include a third O-ring seal OR3 between the second opening/closing device 115 and the viewport 170. The third O-ring seal OR3 may maintain the sealing of the through hole 111H.

The OES device 180 may be connected to the viewport 170. In an embodiment, the OES device 180 may be configured to be removable from the viewport 170. The OES device 180 may analyze plasma light, which has been transmitted from the process space 110S through the viewport 170, and analyze the state of plasma. For example, the OES device 180 may separate the plasma light into a wavelength spectrum and measure the intensity of the plasma light according to wavelength.

In an embodiment, the substrate treating apparatus 100a may further include a fourth O-ring seal OR4 between the viewport 170 and the OES device 180. The fourth O-ring seal OR4 may maintain the sealing of the through hole 111H.

FIGS. 5A to 5D are cross-sectional views illustrating the operation of the substrate treating apparatus 100, according to an embodiment.

Referring to FIG. 5A, the second opening/closing device 115 may be closed. For example, the second power unit 133 may provide power to the opening/closing door structure 115b of the second opening/closing device 115 such that the opening/closing door structure 115b moves toward the second opening 1150 in the second horizontal direction (the Y direction) and blocks the second opening 1150. Accordingly, the second opening/closing device 115 may be closed. Subsequently, the viewport 170 (FIG. 2A) and the OES device 180 (FIG. 2A), which are sequentially connected to the second opening/closing device 115 may be detached from the second opening/closing device 115. At this time, because the second opening/closing device 115 is closed, the vacuum state of the process space 110S may be maintained even when the viewport 170 and the OES device 180 are detached from the second opening/closing device 115.

In an embodiment, when the substrate treating apparatus 100 includes the third O-ring seal OR3 between the second opening/closing device 115 and the viewport 170 and the fourth O-ring seal OR4 between the viewport 170 and the OES device 180, the O-ring seals OR3 and OR4 may be detached in the process of detaching the viewport 170 and the OES device 180.

Referring to FIG. 5B, the seal structure 120 may be connected to the second opening/closing device 115 in the resultant structure of FIG. 5A subsequent to the OES device 180 and the O-ring seals OR3 and OR4 being detached. For example, the bellows seal 121 may be connected to the second opening/closing device 115, and the magnetic fluid seal 123 may be connected to the bellows seal 121. In an embodiment, the second O-ring seal OR2 may also be connected between the second opening/closing device 115 and the bellows seal 121 when the bellows seal 121 is connected to the second opening/closing device 115.

Referring to FIG. 5C, the first opening/closing device 113, which has been closed during plasma processing in the process space 110S, and the second opening/closing device 115, which has been closed as described above with reference to FIG. 5A, may be opened in the resultant structure of FIG. 5B. For example, the first power unit 131 may provide power to at least one opening/closing blade 113b such that the opening/closing blade 113b moves clockwise, and accordingly, the first opening 1130 may be formed so that the first opening/closing device 113 may be opened. In addition, the second power unit 133 may provide power to the opening/closing door structure 115b of the second opening/closing device 115 such that the opening/closing door structure 115b moves away from the second opening 1150 of the second opening/closing device 115 in the second horizontal direction (the Y direction), and accordingly, the second opening 1150 may be opened so that the second opening/closing device 115 may be opened.

In an embodiment, the diameter of the first opening 1130 may be adjusted. For example, the diameter of the first opening 1130 may be adjusted according to the diameter of the plasma density measurement probe PDP, which is described below with reference to FIG. 5D.

Referring to FIG. 5D, in the resultant structure of FIG. 5C, the plasma density measurement probe PDP may be introduced into the process space 110S through the second opening/closing device 115 that is opened, the through hole 111H, and the first opening/closing device 113 that is opened. Subsequently, the density of plasma generated in the process space 110S may be measured by the plasma density measurement probe PDP. In the process of measuring the density of plasma, the plasma density measurement probe PDP may move in the first horizontal direction (the X direction) or may rotate and move in the process space 110S. Despite the movement in the first horizontal direction (the X direction) or the rotational movement of the plasma density measurement probe PDP, the vacuum state of the process space 110S may be maintained by the seal structure 120.

In the case of a process chamber according to the related art and a substrate treating apparatus including the same, an opening/closing device for maintaining the vacuum state of the process chamber is not separately included in the process chamber. Accordingly, in the process of introducing a plasma density measurement probe into the process chamber and measuring the density of plasma generated in the process chamber using the plasma density measurement probe, a process space of the process chamber is in communication with the outside of the process chamber, and therefore, the vacuum state of the process chamber is not maintained. In this case, after the density of plasma is measured, a separate process of changing the process space of the process chamber into the vacuum state needs to be performed, and therefore, the productivity of semiconductor manufacturing processes performed using the process chamber and the substrate treating apparatus including the same decreases. Contrarily, according to aspects of the present inventive concept, the substrate treating apparatus 100 includes the process chamber 110 including the first opening/closing device 113 and the second opening/closing device 115 and the seal structure 120 connected to the second opening/closing device 115, and accordingly, the process space 110S of the process chamber 110 may be maintained in a vacuum state even during a process of introducing the plasma density measurement probe PDP into the process chamber 110 and measuring the density of plasma generated in the process chamber 110 by using the plasma density measurement probe PDP. As a result, after the density of plasma is measured, a separate process of changing the process space 110S of the process chamber 110 into the vacuum state is not performed, and therefore, the productivity of semiconductor manufacturing processes may increase.

While aspects of the inventive concept have been particularly shown and described with reference to embodiments thereof, it will be understood that various changes in form and details may be made therein without departing from the spirit and scope of the following claims.

What is claimed is:

1. A process chamber comprising:
a housing providing a process space where plasma processing is performed;
a first opening/closing device in a side wall of the housing, the first opening/closing device including a first frame and at least one opening/closing blade connected to the first frame; and
a second opening/closing device on an outside of the side wall of the housing and on a same line as the first opening/closing device, the second opening/closing device including a second frame and an opening/closing door structure connected to the second frame,
wherein the first opening/closing device and the second opening/closing device are configured to maintain a vacuum state of the process space.

2. The process chamber of claim 1, wherein the first opening/closing device has an aperture shape, the at least one opening/closing blade includes a plurality of opening/closing blades, respective inner portions of the plurality of opening/closing blades together form a first opening, and a diameter of the first opening varies with a movement of the plurality of opening/closing blades.

3. The process chamber of claim 1, wherein the second frame has a second opening having a circular shape, and the opening/closing door structure is configured to block or open the second opening in a sliding manner.

4. The process chamber of claim 1, wherein the opening/closing door structure includes an opening/closing door and a door seal surrounding the opening/closing door.

5. The process chamber of claim 4, wherein the door seal includes an O-ring seal configured to maintain the vacuum state of the process space.

6. The process chamber of claim 1, wherein the second frame has a second opening having a circular shape, and a diameter of the opening/closing door structure is greater than or equal to a diameter of the second opening.

7. The process chamber of claim 1, further comprising an O-ring seal between the second opening/closing device and the side wall of the housing.

8. A substrate treating apparatus comprising:
a process chamber including a housing providing a process space where plasma processing is performed, a first opening/closing device in a side wall of the housing, the first opening/closing device including a first frame and at least one opening/closing blade connected to the first frame, wherein an inner portion of the at least one opening/closing blade forms a first opening, and a second opening/closing device on an outside of the side wall of the housing and on a same line as the first opening/closing device, the second opening/closing device including a second frame having a circular shape and an opening/closing door structure connected to the second frame;
a substrate support inside the process chamber and configured to support a substrate;
an upper electrode above the substrate support and spaced apart from substrate support;
a power generator configured to apply, to the upper electrode, source power for generating plasma in the process space of the process chamber; and
a seal structure connected to the second opening/closing device,
wherein the first opening/closing device, the second opening/closing device, and the seal structure are configured to maintain a vacuum state of the process space.

9. The substrate treating apparatus of claim 8, wherein the first opening/closing device has an aperture shape, the at least one opening/closing blade includes a plurality of opening/closing blades, and a diameter of the first opening varies with a movement of the plurality of opening/closing blades.

10. The substrate treating apparatus of claim 8, further comprising a first power unit configured to move the at least one opening/closing blade.

11. The substrate treating apparatus of claim 8, wherein the opening/closing door structure includes an opening/closing door and a door seal surrounding the opening/closing door, and the door seal includes an O-ring seal configured to maintain the vacuum state of the process space.

12. The substrate treating apparatus of claim 8, further comprising a second power unit configured to move the opening/closing door structure.

13. The substrate treating apparatus of claim 8, wherein each of the first opening/closing device and the second opening/closing device is at a higher vertical level than the substrate support.

14. The substrate treating apparatus of claim 8, wherein the seal structure is configured to be removable from the second opening/closing device.

15. The substrate treating apparatus of claim 8, further comprising an O-ring seal between the seal structure and the second opening/closing device.

16. The substrate treating apparatus of claim 8, wherein the seal structure includes a bellows seal and a magnetic fluid seal.

17. The substrate treating apparatus of claim 16, further comprising a third power unit configured to drive the bellows seal.

18. An operating method of a substrate treating apparatus, the operating method comprising:
closing a first opening/closing device by blocking a first opening by moving an opening/closing blade of the first opening/closing device and closing a second opening/closing device by blocking a second opening by moving an opening/closing door structure of the second opening/closing device in a horizontal direction;
connecting a seal structure to the second opening/closing device that has been closed;
opening the first opening/closing device by forming the first opening by moving the opening/closing blade of the first opening/closing device and opening the second opening/closing device by opening the second opening by moving the opening/closing door structure of the second opening/closing device in the horizontal direction; and
introducing a plasma density measurement probe into a process space of a process chamber through the second opening of the second opening/closing device that is open and the first opening of the first opening/closing device that is open,
wherein the first opening/closing device, the second opening/closing device, and the seal structure are configured to maintain a vacuum state of the process space.

19. The operating method of claim 18, wherein the opening of the first opening/closing device includes moving the opening/closing blade of the first opening/closing device counterclockwise, wherein an inner portion of the opening/closing blade forms the first opening.

20. The operating method of claim 18, wherein the opening of the second opening/closing device includes moving the opening/closing door structure of the second opening/closing device in the horizontal direction, wherein the opening/closing door structure moves away from the second opening of the second opening/closing device.
